(19) United States
(12) Patent Application Publication
(10) Pub. No.: US 2026/0068598 A1
(43) Pub. Date: Mar. 5, 2026

(54) FILM FORMATION METHOD, SUSCEPTOR, AND VAPOR GROWTH APPARATUS

(71) Applicants: Kabushiki Kaisha Toshiba, Tokyo (JP); Toshiba Electronic Devices & Storage Corporation, Tokyo (JP)

(72) Inventors: Tsutomu KIYOSAWA, Himeji Hyogo (JP); Masaharu SHIMABAYASHI, Ibo Hyogo (JP)

(21) Appl. No.: 19/057,304

(22) Filed: Feb. 19, 2025

(30) Foreign Application Priority Data
Aug. 30, 2024 (JP) 2024-149982

(51) Int. Cl. H01L 21/687; C23C 16/32; C23C 16/458; H01L 21/02

(52) U.S. Cl. CPC H01L 21/6875; C23C 16/325; C23C 16/4584; C23C 16/4586

(57) ABSTRACT

A film formation method of forming a film on a surface of a wafer using a vapor growth apparatus is provided. The film formation method includes a film forming process of forming a film on the surface of the wafer. The vapor growth apparatus includes a susceptor that supports the wafer. The susceptor includes a plurality of wafer supports that support the wafer from below and rotates around a rotation axis extending in a vertical direction. The plurality of wafer supports are arranged at intervals in a circumferential direction around the rotation axis. The film forming process includes supporting the wafer using the plurality of wafer supports such that a direction in which the rotation axis and each wafer support are connected when seen in the vertical direction is a direction which is different from a cleaving direction of the wafer.

### CROSS-REFERENCE TO RELATED APPLICATION

Priority is claimed on Japanese Patent Application No. 2024-149982, filed Aug. 30, 2024, the content of which is incorporated herein by reference.

### FIELD

Embodiments of the present invention relate to a film formation method, a susceptor, and a vapor growth apparatus.

### BACKGROUND

A vapor growth apparatus for forming a film on a surface of a wafer that is supported by a susceptor from below is known. In such a vapor growth apparatus, a wafer is supported from below by a wafer support with a ring shape of the susceptor in a film forming process of forming a film on the surface of the wafer. Accordingly, the temperature of an outer circumferential part of the wafer is likely to become higher than the temperature of a central part of the wafer due to heat transmitted from the wafer support.

As a result, there is a problem in that a wafer-plane distribution of a film which is formed on the wafer in the outer circumferential part of the wafer deteriorates and a yield of semiconductor elements which are manufactured using the wafer decreases.

### BRIEF DESCRIPTION OF THE DRAWINGS

FIG. 1 is a sectional view illustrating a vapor growth apparatus according to a first embodiment.

FIG. 2 is a sectional view illustrating a part of the vapor growth apparatus according to the first embodiment.

FIG. 3 is a top view illustrating a part of the vapor growth apparatus according to the first embodiment.

FIG. 4 is a diagram illustrating a bottom surface of a crystal lattice of a hexagonal crystal system forming a wafer.

FIG. 5 is a sectional view illustrating a part of the vapor growth apparatus according to the first embodiment when a wafer is carried.

FIG. 6 is a sectional view illustrating a part of a susceptor and a part of a wafer guide according to the first embodiment.

FIG. 7 is a sectional view taken along line VII-VII in FIG. 6.

FIG. 8 is a diagram illustrating an arrangement relationship between a crystal orientation of a wafer and a plurality of wafer supports according to the first embodiment.

FIG. 9 is a diagram illustrating an arrangement relationship between measurement positions of a wafer on which a film has been formed and a plurality of wafer supports according to the first embodiment.

FIG. 10 is a block diagram illustrating a part of the vapor growth apparatus according to the first embodiment.

FIG. 11 is a flowchart illustrating an example of a process flow of a film formation method of forming a film on a surface of a wafer using the vapor growth apparatus according to the first embodiment.

FIG. 12 is a diagram illustrating a plurality of wafer supports according to a modified example of the first embodiment.

FIG. 13 is a top view of a susceptor according to a second embodiment.

FIG. 14 is a top view of a susceptor according to a third embodiment.

### DETAILED DESCRIPTION

A film formation method according to an embodiment is a film formation method of forming a film on a surface of a wafer using a vapor growth apparatus. The film formation method according to the embodiment includes a film forming process of forming a film on the surface of the wafer. The vapor growth apparatus includes a susceptor that supports the wafer. The susceptor includes a plurality of wafer supports that support the wafer from below and rotates around a rotation axis extending in a vertical direction. The plurality of wafer supports are arranged at intervals in a circumferential direction around the rotation axis. The film forming process includes supporting the wafer using the plurality of wafer supports such that a direction in which the rotation axis and each wafer support are connected when seen in the vertical direction is a direction which is different from a cleaving direction of the wafer.

Hereinafter, a film formation method, a susceptor, and a vapor growth apparatus according to an embodiment will be described with reference to the accompanying drawings. A Z axis indicating a vertical direction is appropriately illustrated in the drawings. A side (+Z side) to which an arrow of the Z axis is directed is an upper side in the vertical direction, a side opposite to the side to which the arrow of the Z axis is directed is a lower side in the vertical direction. In the following description, the vertical direction is referred to as a “vertical direction Z,” the upper side in the vertical direction Z is simply referred to as an “upper side,” and the lower side in the vertical direction Z is simply referred to as a “lower side.” In the drawings, a rotation axis R extending in the vertical direction Z is appropriately illustrated. The rotation axis R is a virtual line. In the following description, unless otherwise mentioned, a radial direction from the rotation axis R is simply referred to as a “radial direction,” and a circumferential direction around the rotation axis R is simply referred to as a “circumferential direction.”

### First Embodiment

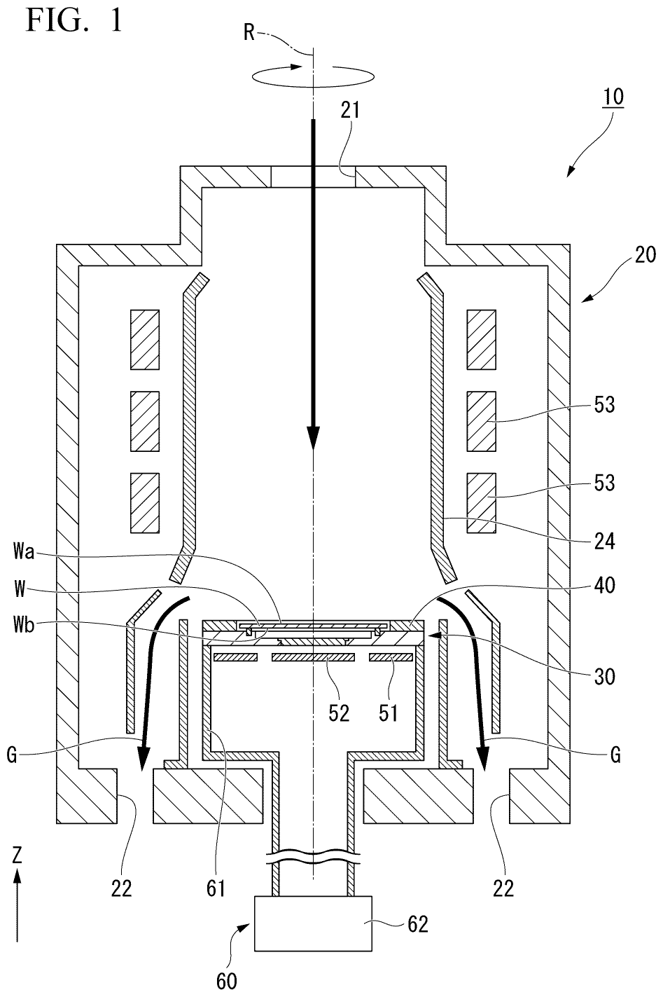

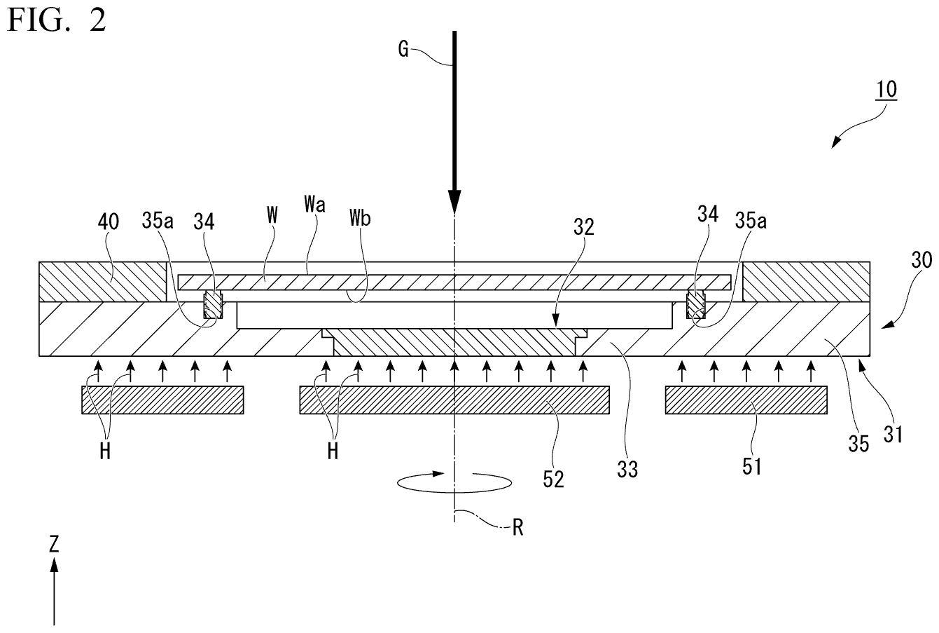

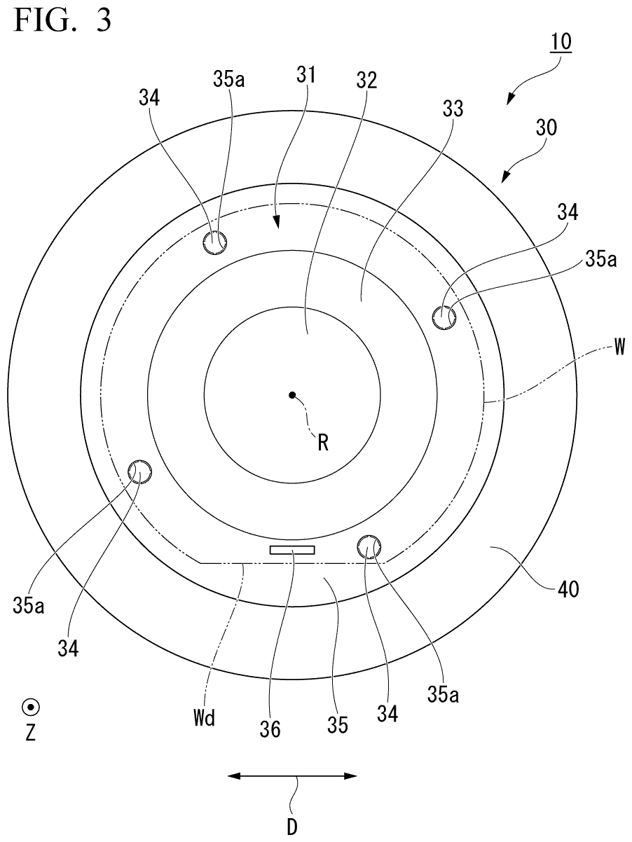

FIG. 1 is a sectional view illustrating a vapor growth apparatus 10 according to a first embodiment. FIG. 2 is a sectional view illustrating a part of the vapor growth apparatus 10 according to the first embodiment. FIG. 3 is a top view illustrating a part of the vapor growth apparatus 10 according to the first embodiment. In FIG. 3, an outline of a wafer W is indicated by an alternate long and two short dashes line. The vapor growth apparatus 10 illustrated in FIGS. 1 to 3 is am apparatus for forming a film on a surface of a wafer W. In the vapor growth apparatus 10, for example, an epitaxial film is formed on the surface of the wafer W using a chemical vapor deposition (CVD) method. The film formed on the surface of the wafer W is, for example, a film formed of silicon carbide (SiC), that is, an SiC film. The film formed on the surface of the wafer W may be a film formed of another material such as Si. In the first embodiment, the wafer W is formed by single crystal with a crystal structure of a hexagonal crystal system. The wafer W is formed of, for example, silicon carbide (SIC). That is, the wafer W is a SiC substrate. The material of the wafer W is, for example, 4H-SiC or 6H-SiC. The wafer W may be formed of another material such as silicon (Si).

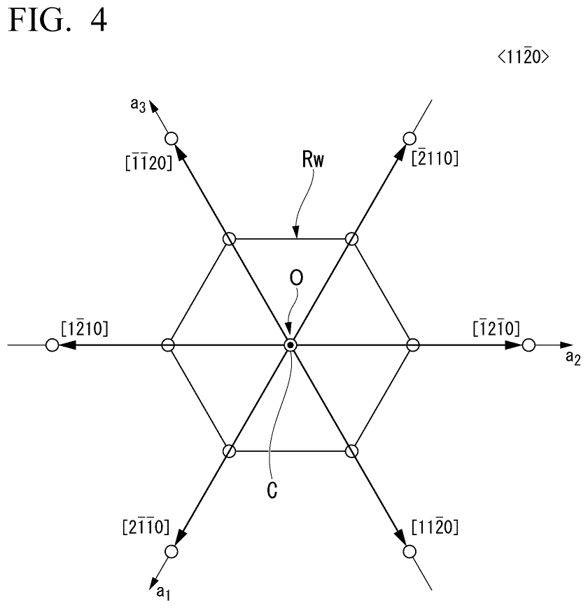

As illustrated in FIG. 3, a wafer W has a substantially disc shape. A part of an outer edge of the wafer W is an orientation flat Wd extending in a straight shape. That is, the orientation flat Wd is provided on the outer edge of the wafer W in the first embodiment. The orientation flat Wd in the first embodiment extends in one direction of a cleaving direction of the wafer W. The “cleaving direction” is a direction in which the wafer W is likely to crack and which is determined by a crystal structure of the wafer W. The cleaving direction of the wafer W is a direction along a cleaving surface which is formed when the wafer W cracks in the cleaving direction. FIG. 4 is a diagram illustrating a bottom surface of a crystal lattice Rw of a hexagonal crystal system forming the wafer W. As illustrated in FIG. 4, in the crystal structure of the hexagonal crystal system, directions indicated by four unit vectors including an a1 vector, an a2 vector, an a3 vector, and a c vector with the center of the bottom surface of the crystal lattice Rw as an origin are expressed as direction indices which are Miller indices using a minimum integer ratio of a coefficient of each unit vector. Here, a plate face of the wafer W is a plane almost parallel to a crystal face expressed by a plane index (0001) of the Miller indices. In other words, the wafer W is a wafer which is formed of a substrate in which a C face of the crystal lattice expressed by (0001) almost parallel to the plate face of the wafer W, that is, a substrate with an orientation of C (0001). Here, the case in which the plate face of the wafer W is almost parallel to the crystal face expressed by (0001) includes, for example, a case in which the wafer W is a SiC substrate with an off angle of which the plate face is offset by several degrees from the face (0001) to stabilize the crystal structure of a film to grow epitaxially. The off angle in the SiC substrate with an off angle is, for example, equal to or greater than 1° and equal to or less than 4°. The a1 vector, the a2 vector, and the a3 vector are unit vectors which are different from each other by 120° and which indicate directions directed from the origin O to atoms defining the outer circumference of the bottom surface of the crystal lattice Rw. When the plate face of the wafer W is almost parallel to the crystal face expressed by (0001), the a1 vector, the a2 vector, and the a3 vector are vectors with the directions almost parallel to the plate face of the wafer W. A sum of the coefficient of the a1 vector, the coefficient of the a2 vector, and the coefficient of the a3 vector is zero. The c vector is a unit vector indicating a height direction perpendicular to the a1 vector, the a2 vector, and the a3 vector. When the plate face of the wafer W is almost parallel to the crystal face expressed by (0001), the c vector is a vector with a direction almost parallel to a thickness direction of the wafer W.

For example, a crystal orientation expressed by [11-20] in FIG. 4 represents that the coefficient of the a1 vector, the coefficient of the a2 vector, the coefficient of the a3 vector, and the coefficient the c vector are 1:1:−2:0. In the Miller indices, when a coefficient has a negative value, the coefficient is expressed by an overbar of a numerical value, but the case in which a coefficient is negative is expressed by adding “−” to the front of a numerical value instead of adding a bar over the numerical value in the description other than the drawings. Six crystal orientations of [11-20], [−12-10], [−2110], [−1-120], [1-210], and [Feb. 1, 2010] are illustrated in FIG. 4. These six crystal orientations are equivalent directions and are expressed by <11-20>. A crystal orientation equivalent to a certain crystal orientation is a crystal orientation which becomes the same direction as the certain crystal orientation by rotating the crystal and which cannot be distinguished from the certain crystal orientation. The crystal orientation expressed by <11-20> in the hexagonal crystal system is a direction in which the crystal is likely to crack, that is, a cleaving direction. In the first embodiment, the orientation flat Wd extends in the crystal orientation of the wafer W expressed by <11-20>. As illustrated in FIG. 3, a part of an outer edge of the wafer W other than the orientation flat Wd forms a circular arc. The wafer W is disposed in the vapor growth apparatus 10 in a state in which a top surface Wa on which a film is formed faces upward and a bottom surface Wb opposite to the top surface Wa faces downward. Even when the wafer W is the SiC substrate with an off angle, the direction of <11-20> when seen in the thickness direction of the wafer W is the same or almost the same as that when the wafer W is a SiC substrate with an off angle of 0°.

As illustrated in FIG. 1, the vapor growth apparatus 10 includes a chamber 20, a supply pipe 24, a susceptor 30, a wafer guide 40, a first heating unit 51, a second heating unit 52, a third heating unit 53, and a drive unit 60.

The chamber 20 accommodates the supply pipe 24, the susceptor 30, the wafer guide 40, the first heating unit 51, the second heating unit 52, the third heating unit 53, and the drive unit 60 therein. The chamber 20 is formed of, for example, a metal such as stainless steel (SUS). The chamber 20 has a cylindrical shape extending in the vertical direction Z. A supply port 21 is formed in the top plate of the chamber 20. A discharge port 22 is formed in the bottom of the chamber 20. A gas G including a source gas for forming a film on the wafer W is supplied into the chamber 20 from the supply port 21.

The supply pipe 24 has a cylindrical shape extending in the vertical direction Z. The supply pipe 24 is open upward and downward. The gas G supplied into the chamber 20 from the supply port 21 flows downward in the supply pipe 24. The gas G flowing downward in the supply pipe 24 is supplied to the wafer W placed on the susceptor 30. An excess gas G of the gas G supplied into the chamber 20 is discharged to the outside of the chamber 20 via the discharge port 22.

By allowing the source gas included in the gas G to react with a surface of the wafer W, an epitaxial film is formed on the surface of the wafer W. The source gas is, for example, a gas including an Si-based gas and a C-based gas. Examples of the Si-based gas include silane (SiH₄), dichlorosilane (SiH₂Cl₂), trichlorosilane (SiHCl₃), and tetrachlorosilane (SiCl₄). An example of the C-based gas is propane (C₃H₈). In the first embodiment, the source gas is, for example, a gas including silane (SiH₄) and propane (C₃H₈).

In the first embodiment, the chamber 20 is also supplied with use a gas other than the source gas from the supply port 21. Examples of the other gas include an impurity gas, a carrier gas, and hydrogen chloride (HCl) gas. Examples of the impurity gas include an N-type impurity gas such as nitrogen and a P-type impurity gas such as trimethyl aluminum (TMA). Examples of the carrier gas include argon gas and hydrogen gas. More specifically, the carrier gas which is used when a wafer W is carried into the vapor growth apparatus 10 and is placed on the susceptor 30 and when a wafer W on which a film has been formed is detached from the susceptor 30 and is carried out of the vapor growth apparatus 10 is argon gas. The carrier gas which is used at the time of film formation is hydrogen gas.

The susceptor 30 is a support member that supports a wafer W from below. The susceptor 30 is supported by the drive unit 60 from below. As illustrated in FIG. 2, the susceptor 30 includes a base 31, a movable portion 32, and a plurality of wafer supports 34. The base 31, the movable portion 32, and the plurality of wafer supports 34 are separate from each other. The base 31, the movable portion 32, and the plurality of wafer supports 34 are formed of, for example, poly-SiC. The base 31, the movable portion 32, and the plurality of wafer supports 34 may be formed of graphite. In this case, a coated layer formed of SiC may be provided on the surfaces of the base 31, the movable portion 32, and the plurality of wafer supports 34.

In the first embodiment, the base 31 has a ring shape surrounding the rotation axis R. The base 31 includes an inner ring-shaped portion 33 and a guide support 35. As illustrated in FIG. 3, the inner ring-shaped portion 33 has a ring shape surrounding the rotation axis R. In the first embodiment, an inner edge in the radial direction of the inner ring-shaped portion 33 is an inner edge in the radial direction of the base 31.

The guide support 35 is located outside of the inner ring-shaped portion 33 in the radial direction. In the first embodiment, the guide support 35 has a ring shape surrounding the rotation axis R. More specifically, the guide support 35 has a substantially ring shape centered on the rotation axis R. The guide support 35 is a portion supporting the wafer guide 40 from below. As illustrated in FIG. 2, an inner edge of the guide support 35 in the radial direction in the first embodiment is connected to an outer edge of the inner ring-shaped portion 33 in the radial direction. A top surface of the guide support 35 is located higher than the top surface of the inner ring-shaped portion 33. A bottom surface of the wafer guide 40 comes into contact with an outer portion of the top surface of the guide support 35 in the radial direction.

The movable portion 32 is provided inside of the inner ring-shaped portion 33 of the base 31 in the radial direction. The movable portion 32 is fitted into the inner ring-shaped portion 33 of the base 31 in the radial direction. In the state in which the wafer W is placed on the susceptor 30, the bottom surface Wb of the wafer W is separated upward from the top surface of the inner ring-shaped portion 33 and the top surface of the movable portion 32. A gap is provided between the wafer W and the inner ring-shaped portion 33 in the vertical direction Z and between the wafer W and the movable portion 32 in the vertical direction Z.

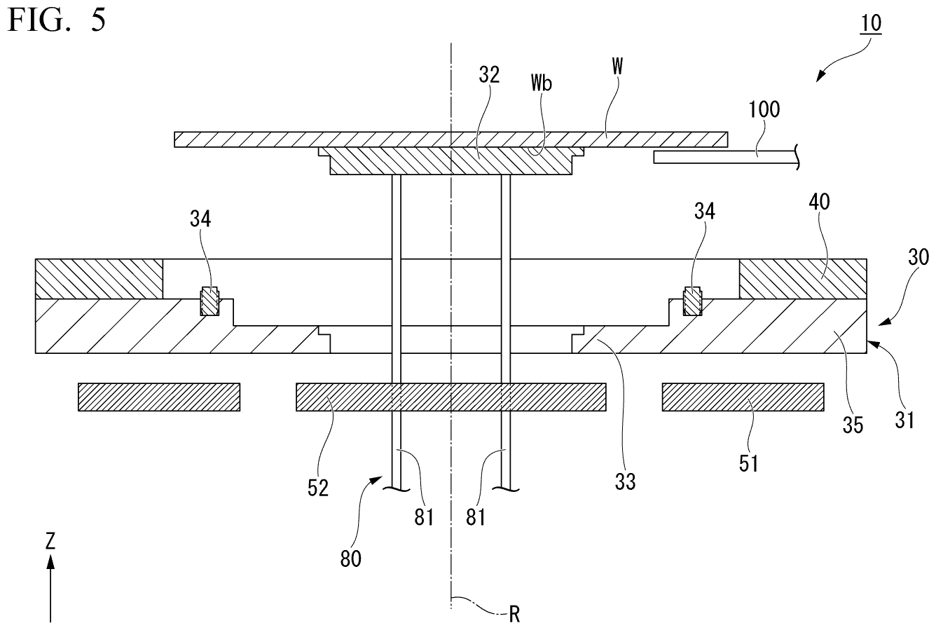

The movable portion 32 is movable in the vertical direction Z. FIG. 5 is a sectional view illustrating a part of the vapor growth apparatus 10 when a wafer Wis carried. As illustrated in FIG. 5, when a wafer W is carried, the movable portion 32 moves upward from the inner ring-shaped portion 33. In the first embodiment, the movable portion 32 moves in the vertical direction Z by a lifting unit 80. The lifting unit 80 includes a plurality of movable pins 81 which are located below the movable portion 32. The lifting unit 80 moves the movable portion 32 upward by moving the plurality of movable pins 81 upward and pushing the movable portion 32 from below to above using the plurality of movable pins 81. The plurality of movable pins 81 go over a gap provided in the second heating unit 52 and moves upward from the second heating unit 52 to push the movable portion 32 upward.

When a wafer W is carried onto the susceptor 30, the wafer W carried by a carrying unit 100 is placed on the movable portion 32 which is located higher than the inner ring-shaped portion 33. When the movable portion 32 is moved downward by the lifting unit 80 in this state, an outer portion of the wafer W in the radial direction is supported from below by the wafer supports 34, and the wafer W is placed on the susceptor 30. When the wafer W is carried from the susceptor 30, the movable portion 32 moves upward, and the wafer W is pushed upward from the wafer supports 34 and the wafer guide 40 by the movable portion 32. In this state, the wafer W is carried from the movable portion 32 by the carrying unit 100.

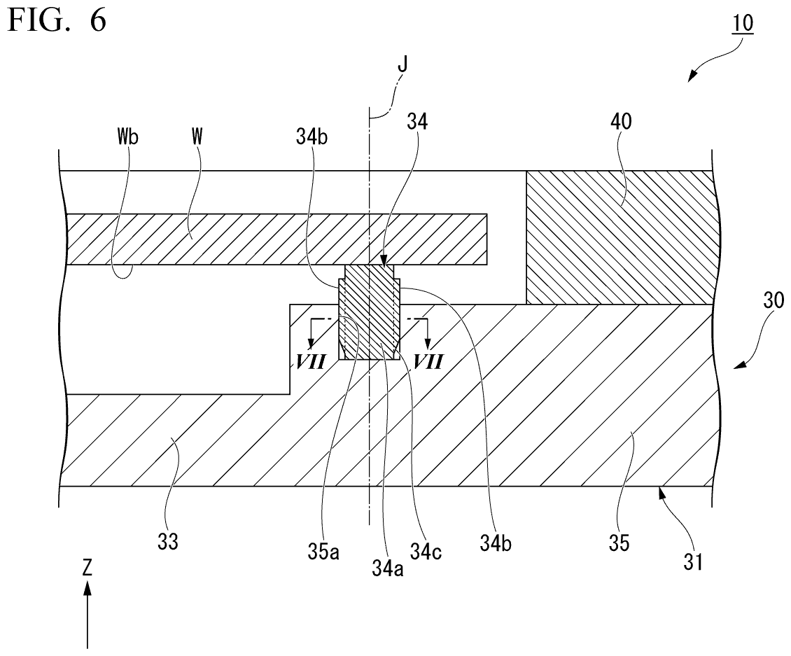

As illustrated in FIG. 3, the base 31 includes a plurality of fixing holes 35a which are open upward. The plurality of fixing holes 35a are arranged at intervals in the circumferential direction. In the first embodiment, the plurality of fixing holes 35a are arranged at equal intervals on one circumference in the circumferential direction. In the first embodiment, the number of fixing holes 35a is four. In the first embodiment, the fixing holes 35a are circular holes when seen in the vertical direction Z. In the first embodiment, the fixing holes 35a are formed in an inner portion of the guide support 35 in the radial direction. FIG. 6 is a sectional view illustrating a part of the susceptor 30 and a part of the wafer guide 40. As illustrated in FIG. 6, the fixing hole 35a is recessed downward from the top surface of the guide support 35. The fixing hole 35a is a hole with a bottom. The fixing hole 35a may be a hole penetrating the base 31 in the vertical direction Z.

As illustrated in FIG. 3, a marked portion 36 is formed in the base 31. The marked portion 36 is a portion indicating a predetermined direction which the orientation flat Wd provided on the outer edge of the wafer W is set to be parallel to when the wafer W is supported by the plurality of wafer supports 34. The predetermined direction is a direction perpendicular to the vertical direction Z. In FIG. 3, the predetermined direction is a right-left direction in FIG. 3 and is indicated by an arrow D. In the following description, the predetermined direction indicated by the marked portion 36 is referred to as a “predetermined direction D.” In the first embodiment, the marked portion 36 is a mark extending in the predetermined direction D. The marked portion 36 is formed in an inner part in the radial direction of the top surface of the guide support 35. In the first embodiment, the marked portion 36 is located below a part of the outer edge in the radial direction of the wafer W located inside of the orientation flat Wd in the radial direction when the wafer W is placed on the susceptor 30. That is, the marked portion 36 in the first embodiment is covered with the wafer W from above.

The plurality of wafer supports 34 are portions for supporting a wafer W from below. The plurality of wafer supports 34 support a part on an outer circumferential side of a wafer W from below. The plurality of wafer supports 34 support an outer part of the wafer W in the radial direction from below. More specifically, the plurality of wafer supports 34 support a part close to the outer edge of the wafer W in the radial direction from below. The plurality of wafer supports 34 are arranged at intervals in the circumferential direction around the rotation axis R. In the first embodiment, the plurality of wafer supports 34 are arranged at equal intervals on one circumference in the circumferential direction. In the first embodiment, the number of wafer supports 34 is four.

As illustrated in FIG. 6, in the first embodiment, the plurality of wafer supports 34 have a columnar shape extending in the vertical direction Z. The plurality of wafer supports 34 are fixed into the plurality of fixing holes 35a, respectively. In the first embodiment, a lower part of each wafer support 34 is fixed into the corresponding fixing hole 35a. Each wafer support 34 is fixed into the corresponding fixing hole 35a, for example, by press fitting. The plurality of wafer supports 34 protrude upward from the inside of the plurality of fixing holes 35a. That is, an upper end of each wafer support 34 is located higher than an upper end of each fixing hole 35a. The upper end of each wafer support 34 comes into contact with the bottom surface Wb of the wafer W.

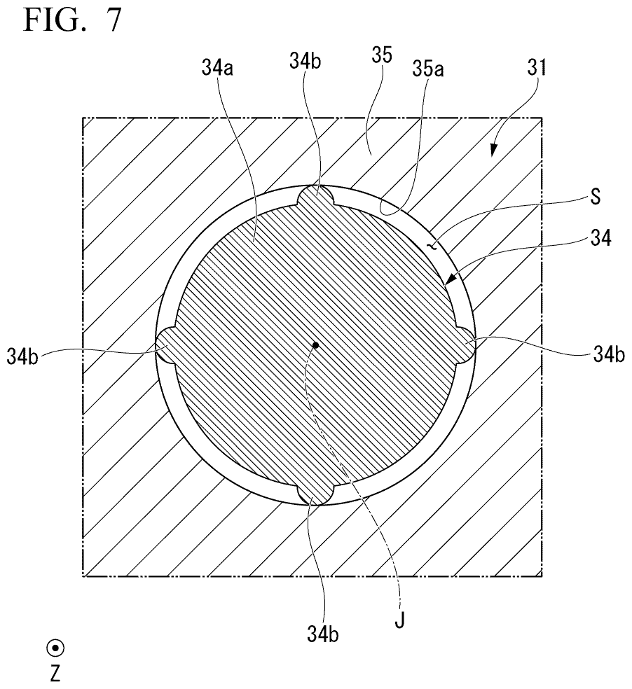

Each of the plurality of wafer supports 34 includes a body portion 34a and a protruding portion 34b. The body portion 34a has a columnar shape extending in the vertical direction Z. FIG. 7 is a sectional view of a wafer support 34 taken along line VII-VII taken in FIG. 6. As illustrated in FIG. 7, in the first embodiment, the body portion 34a has a columnar shape extending the vertical direction Z around a center axis J. The center axis J is a virtual line extending in the vertical direction Z. The outer diameter of the body portion 34a is smaller than the inner diameter of the fixing hole 35a. The outer circumferential surface of the body portion 34a is separated from the inner surface of the fixing hole 35a. As illustrated in FIG. 6, the bottom surface of the body portion 34a comes into contact with the bottom surface of the fixing hole 35a. The bottom surface of the body portion 34a is, for example, a plane perpendicular to the vertical direction Z. The top surface of the body portion 34a comes into contact with the bottom surface Wb of the wafer W. The top surface of the body portion 34a is, for example, a plane perpendicular to the vertical direction Z.

The top surface of the body portion 34a may have, for example, an arc shape which is convex upward in a section including the center axis J. In other words, the upper end of the body portion 34a may have, for example, a semispherical shape which is convex upward. For example, the upper end of the body portion 34a may have a conical shape which is convex upward or a pyramid shape which is convex upward. In this case, a vertex in the upper end of the body portion 34a comes into contact with the bottom surface Wb of the wafer W.

The protruding portion 34b is provided on the outer circumferential surface of the body portion 34a. The outer circumferential surface of the body portion 34a is an outer surface in a radial direction centered on the center axis J in the outer surfaces of the body portion 34a. In the following description, the radial direction centered on the center axis J may be referred to as a “second radial direction.” The protruding portion 34b protrudes outward in the second radial direction from the outer circumferential surface of the body portion 34a. As illustrated in FIG. 7, in the first embodiment, the outer surface in the second radial direction of the protruding portion 34b has an arc shape which is convex outward in the second radial direction in a section perpendicular to the vertical direction Z. In the first embodiment, the protruding portion 34b has a semicircular shape which is convex outward in the second radial direction in a section perpendicular to the vertical direction Z. As illustrated in FIG. 6, in the first embodiment, the protruding portion 34b is a rib extending in the vertical direction Z. The upper end of the protruding portion 34b is located lower than the upper end of the body portion 34a. The lower end of the protruding portion 34b is located higher than the lower end of the body portion 34a. The lower end of the protruding portion 34b is an inclined portion 34c in which a size in the second radial direction decreases downward. The lower part of the protruding portion 34b is located in the fixing hole 35a. The upper part of the protruding portion 34b is located higher than the fixing hole 35a.

As illustrated in FIG. 7, the protruding portion 34b comes into contact with the inner surface of the fixing hole 35a. More specifically, an outer end in the second radial direction of a part of the protruding portion 34b located in the fixing hole 35a comes into contact with the inner surface of the fixing hole 35a. A plurality of protruding portions 34b are provided at intervals in the circumferential direction around the center axis J. The plurality of protruding portions 34b are arranged at equal intervals on one circumference in the circumferential direction around the center axis J. In the first embodiment, the number of protruding portions 34b is four. In the first embodiment, the plurality of protruding portions 34b are deformed in the second radial direction when the wafer support 34 is pressed into the fixing hole 35a. For example, the plurality of protruding portions 34b are in a state in which it is elastically deformed in the second radial direction in the fixing holes 35a. As described above, since the inclined portion 34c is provided at the lower end of each protruding portion 34b, the wafer support 34 can be easily inserted into the fixing hole 35a when the wafer support 34 is pressed into the upper opening of the fixing hole 35a.

In each of the plurality of wafer supports 34, at least a part of the outer circumferential surface of the part of the wafer support 34 located in the fixing hole 35a is separated from the inner surface of the fixing hole 35a. The outer circumferential surface of the part of the wafer support 34 located in the fixing hole 35a includes an outer circumferential surface of a part of the body portion 34a located in the fixing hole 35a and an outer surface in the second radial direction of parts of the plurality of protruding portion 34b located in the fixing hole 35a. In the first embodiment, outer ends in the second radial direction of the plurality of protruding portions 34b come into contact with the inner surface of the fixing hole 35a, and the other part of the outer circumferential surface of the part of the wafer support 34 located in the fixing hole 35a is separated inward in the second radial direction from the inner surface of the fixing hole 35a. Accordingly, a gap S is provided between the outer circumferential surface of the wafer support 34 and the inner surface of the fixing hole 35a. In the first embodiment, the gap S is a void filled with air.

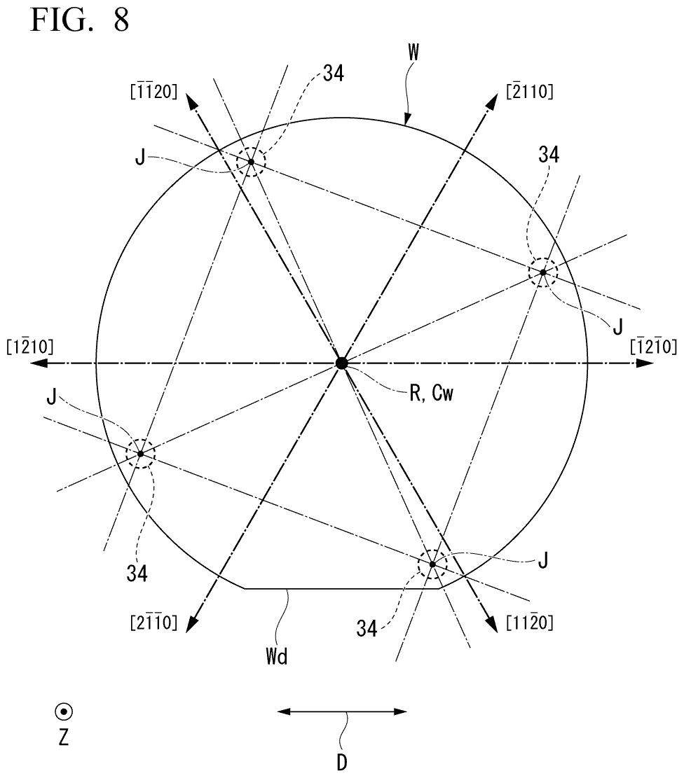

FIG. 8 is a top view of a wafer W in a state in which the wafer is supported by the plurality of wafer supports 34 and is a diagram illustrating an arrangement relationship between a crystal orientation of the wafer W and the plurality of wafer supports 34. In FIG. 8, the crystal orientation of the wafer W expressed by <11-20> is indicated by an alternate long and short dash line arrow. As illustrated in FIG. 8, a direction in which the rotation axis R and each wafer support 34 are connected when seen in the vertical direction Z is a direction which is different from the crystal orientation of the wafer W expressed by <11-20>. That is, the direction in which the rotation axis R and each wafer support 34 are connected when seen in the vertical direction Z is a direction which is different from the cleaving direction of the wafer W. In FIG. 8, the direction in which the rotation axis R and each wafer support 34 are connected is indicated by an alternate long and short dash line passing through the rotation axis R and the center axis J of each wafer support 34 when seen in the vertical direction Z. It is preferable that the direction in which the rotation axis R and each wafer support 34 are connected be a direction which is offset by 5° or more from the cleaving direction of the wafer W. It is more preferable that the direction in which the rotation axis R and each wafer support 34 are connected be a direction which is offset by 10° or more from the cleaving direction of the wafer W. It is still more preferable that the direction in which the rotation axis R and each wafer support 34 are connected be a direction which is offset by 15° or more from the cleaving direction of the wafer W.

In this specification, “a direction is different from another direction” means that the direction is not parallel to the other direction. That is, the “direction in which the rotation axis R and each wafer support 34 are connected is a direction which is different from the cleaving direction of the wafer W” means that the direction in which the rotation axis R and each wafer support 34 are connected is not parallel to the cleaving direction of wafer W.

The direction in which the rotation axis R and each wafer support 34 are connected when seen in the vertical direction Z is a direction which is different from the predetermined direction D indicated by the marked portion 36. The direction in which the rotation axis R and each wafer support 34 are connected when seen in the vertical direction Z is a direction which is different from a direction oblique by 60° with respect to the predetermined direction D. In FIG. 8, the predetermined direction D is a crystal orientation indicated by [−12-10] and [1-210]. A direction oblique by 60° with respect to the predetermined direction D is a crystal orientation indicated by [−2110], [−1-120], [Feb. 1, 2010], and [11-20].

A direction in which two arbitrary wafer supports 34 out of the plurality of wafer supports 34 are connected when seen in the vertical direction Z is a direction which is different from the crystal orientation of the wafer W indicated by <11-20>. That is, the direction in which two arbitrary wafer supports 34 out of the plurality of wafer supports 34 are connected when seen in the vertical direction Z is a direction which is different from the cleaving direction of the wafer W. In FIG. 8, the direction in which two arbitrary wafer supports 34 are connected is indicated by an alternate long and short dash line passing through the center axes J of the two wafer supports 34 when seen in the vertical direction Z. It is preferable that the direction in which two arbitrary wafer supports 34 are connected be a direction which is offset by 5° or more from the cleaving direction of the wafer W. It is more preferable that the direction in which two arbitrary wafer supports 34 are connected be a direction which is offset by 10° or more from the cleaving direction of the wafer W. It is still more preferable that the direction in which two arbitrary wafer supports 34 are connected be a direction which is offset by 15° or more from the cleaving direction of the wafer W.

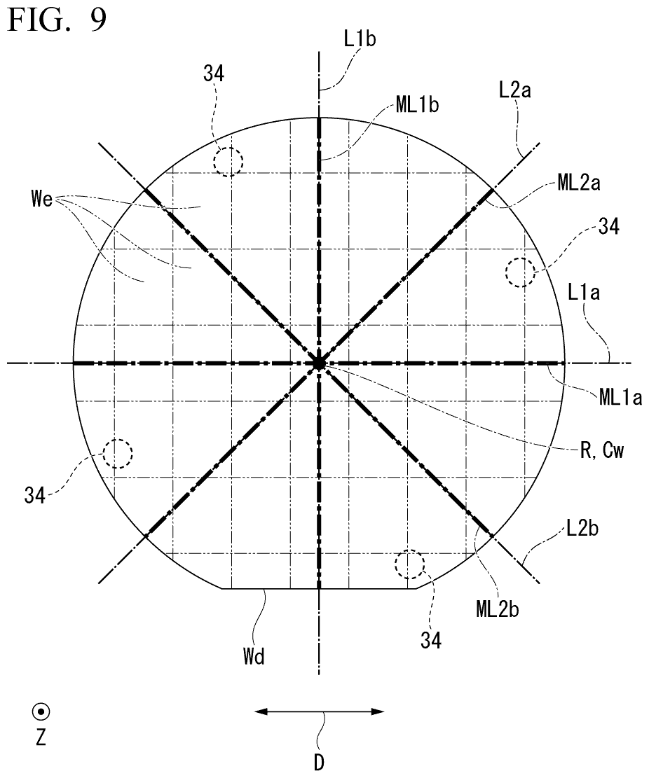

FIG. 9 is a top view of a wafer W in a state in which the wafer is supported by the plurality of wafer supports 34 and is a diagram illustrating an arrangement relationship between a measurement position of the wafer W on which a film has been formed and the plurality of wafer supports 34. Straight lines L1a and L1b illustrated in FIG. 9 are virtual lines extending in a direction perpendicular to the vertical direction Z. The straight line L1a is a straight line passing through the rotation axis R and extending in the predetermined direction D indicated by the marked portion 36 when seen in the vertical direction Z. The straight line L1b is a straight line passing through the rotation axis R and extending in a direction perpendicular to the predetermined direction D when seen in the vertical direction Z. When seen in the vertical direction Z, the plurality of wafer supports 34 are arranged at positions other than the straight line L1a passing through the rotation axis R and extending in the predetermined direction D. When seen in the vertical direction Z, the plurality of wafer supports 34 are arranged at positions other than the straight line L1b passing through the rotation axis R and extending in the direction perpendicular to the predetermined direction D. When seen in the vertical direction Z, for example, it is preferable that the plurality of wafer supports 34 be separated by 5 mm or more from the straight lines L1a and L1b, and it is more preferable that they be separated by 10 mm or more from the straight lines.

Straight lines L2a and L2b illustrated in FIG. 9 are virtual lines extending in the direction perpendicular to the vertical direction Z. The straight lines L2a and L2b are straight lines passing through the rotation axis R and extending in a direction oblique by 45° with respect to the predetermined direction D when seen in the vertical direction Z. The extending direction of the straight line L2a and the extending direction of the straight line L2b are perpendicular to each other. When seen in the vertical direction Z, the plurality of wafer supports 34 are arranged at positions other than the straight lines L2a and L2b passing through the rotation axis R and extending in the direction oblique by 45° with respect to the predetermined direction D. When seen in the vertical direction Z, for example, it is preferable that the plurality of wafer supports 34 be separated by 5 mm or more from the straight lines L2a and L2b, and it is more preferable that they be separated by 10 mm or more from the straight lines.

As illustrated in FIG. 8, in the first embodiment, the plurality of wafer supports 34 include a pair of wafer supports 34 with the rotation axis R interposed therebetween when seen in the vertical direction Z. The pair of wafer supports 34 is provided on the same straight line passing through the rotation axis R when seen in the vertical direction Z. In the first embodiment, two pairs of wafer supports 34 are provided.

As illustrated in FIG. 2, the wafer guide 40 is supported by the susceptor 30 from below. The wafer guide 40 has a ring shape surrounding the rotation axis R. More specifically, as illustrated in FIG. 3, the wafer guide 40 has a ring shape centered on the rotation axis R. The wafer guide 40 surrounds the outer edge of the wafer W. The wafer guide 40 has a plate shape of which a plate face faces the vertical direction Z. The wafer guide 40 is formed of, for example, poly-SiC. The wafer guide 40 may be formed of graphite. In this case, a coated layer formed of SiC may be provided on the surface of the wafer guide 40.

As illustrated in FIG. 2, the wafer guide 40 is supported by the guide support 35 from below. The bottom surface of the wafer guide 40 comes into contact with an outer part in the radial direction of the top surface of the guide support 35. An inner edge in the radial direction of the wafer guide 40 is located outside of the fixing holes 35a and the wafer supports 34 in the radial direction. The bottom surface of the wafer guide 40 is located lower than the upper end of the plurality of wafer supports 34. The top surface of the wafer guide 40 is located higher than the top surface, that is, the top surface Wa, of the wafer W placed on the plurality of wafer supports 34. The upper end of the inner surface in the radial direction of the wafer guide 40 is located higher than the upper ends of the plurality of wafer supports 34. That is, the upper end of the wafer support 34 is located lower than the upper end of the inner surface in the radial direction of the wafer guide 40.

A recessed portion which is recessed in the vertical direction Z may be formed in one of the wafer guide 40 and the guide support 35, and a protruding portion which protrudes in the vertical direction Z and which is fitted into the recessed portion may be formed in the other of the wafer guide 40 and the guide support 35. With this configuration, it is possible to curb departure in the radial direction of the wafer guide 40 from the guide support 35.

As illustrated in FIG. 1, the drive unit 60 rotates the susceptor 30 around the rotation axis R extending in the vertical direction Z. The drive unit 60 includes a susceptor holding unit 61 and a power unit 62. The susceptor holding unit 61 has a cylindrical shape which is open upward. The susceptor 30 is held at the upper end of the susceptor holding unit 61. The susceptor holding unit 61 is located in the chamber 20. The lower end of the susceptor holding unit 61 is located outside of the chamber 20 via an opening formed in the bottom of the chamber 20. The power unit 62 rotates the susceptor holding unit 61 around the rotation axis R. The power unit 62 is, for example, a motor. The power unit 62 is connected to the lower end of the susceptor holding unit 61. The power unit 62 may include a motor and a reduction gear mechanism connected to the motor. In this case, rotation of the motor is transmitted to the susceptor holding unit 61 via the reduction gear mechanism. The power unit 62 is located, for example, outside of the chamber 20.

The first heating unit 51 and the second heating unit 52 are heating units that can heat the susceptor 30. By heating the susceptor 30 using the first heating unit 51 and the second heating unit 52, a wafer W and the wafer guide 40 which are in contact with the susceptor 30 are heated. As illustrated in FIG. 2, in the first embodiment, the first heating unit 51 and the second heating unit 52 are located below the susceptor 30. The first heating unit 51 and the second heating unit 52 heat the susceptor 30 by applying heat H to the susceptor 30 from below. The first heating unit 51 and the second heating unit 52 are located in the susceptor holding unit 61 of the drive unit 60. The first heating unit 51 and the second heating unit 52 are resistor-heating type heaters. The first heating unit 51 and the second heating unit 52 are constituted, for example, by heat transfer lines extending along a plane perpendicular to the vertical direction Z. The first heating unit 51 and the second heating unit 52 may have any structure as long as they can heat a target.

The first heating unit 51 is located outside of the second heating unit 52 in the radial direction. The first heating unit 51 surrounds the second heating unit 52 from the outside in the radial direction. The first heating unit 51 is located below the wafer supports 34 and the guide support 35. At least a part of the first heating unit 51 overlaps the wafer supports 34 when seen in the vertical direction Z. In the first embodiment, an inner part in the radial direction of the first heating unit 51 overlaps the wafer supports 34 when seen in the vertical direction Z. An outer part in the radial direction of the first heating unit 51 overlaps the wafer guide 40 when seen in the vertical direction Z.

The second heating unit 52 is separated inward in the radiation direction from the first heating unit 51. The second heating unit 52 includes a part located below the inner ring-shaped portion 33 and a part located below the movable portion 32. An outer edge in the radial direction of the second heating unit 52 is located below the inner ring-shaped portion 33. A part of the second heating unit 52 located inward in the radial direction from the part located below the inner ring-shaped portion 33 is located below the movable portion 32.

As illustrated in FIG. 1, the third heating unit 53 has a ring shape surrounding the supply pipe 24. In the first embodiment, the vapor growth apparatus 10 includes three third heating units 53. The three third heating units 53 are arranged at intervals in the vertical direction Z. Each third heating unit 53 heats the gas G passing through the supply pipe 24. Accordingly, it is possible to raise the temperature of the gas G when the gas reaches a wafer W. As a result, it is possible to enhance a film formation speed of an SiC film which is formed on the surface of the wafer W. The number of third heating units 53 in the vapor growth apparatus 10 may be two or less or four or more. The third heating units 53 are, for example, resistor-heating type heaters constituted by heat transfer lines. The third heating units 53 may have any structure as long as they can heat a target.

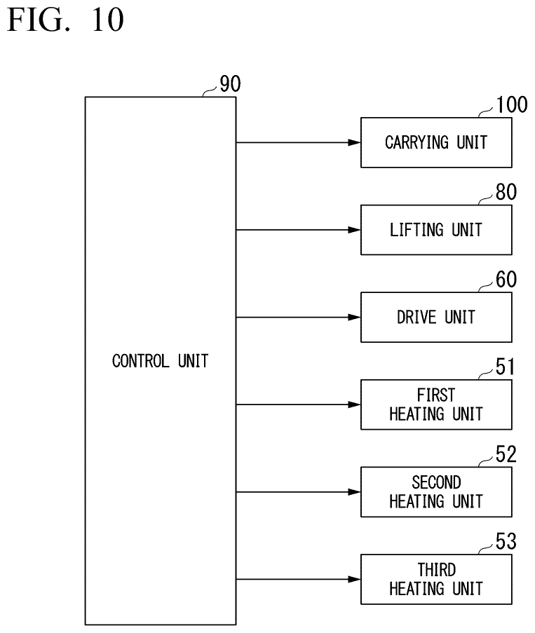

FIG. 10 is a block diagram illustrating a part of the vapor growth apparatus 10. As illustrated in FIG. 10, the vapor growth apparatus 10 includes a control unit 90. The control unit 90 controls the constituents of the vapor growth apparatus 10. The control unit 90 controls the first heating unit 51, the second heating unit 52, the third heating units 53, the drive unit 60, the lifting unit 80, and the carrying unit 100.

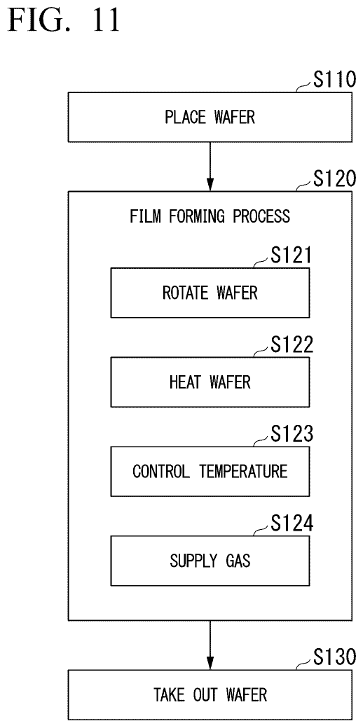

FIG. 11 is a flowchart illustrating an example of a flow of a film formation method of forming a film on a surface of a wafer W using the vapor growth apparatus 10. As illustrated in FIG. 11, the control unit 90 places a wafer W on the susceptor 30 (Step S110). In Step S110, the control unit 90 carries the wafer W using the carrying unit 100 and places the wafer W on the movable portion 32 having moved upward as illustrated in FIG. 5. The control unit 90 controls the lifting unit 80 such that the movable portion 32 moves downward and the wafer W on the movable portion 32 is placed on the plurality of wafer supports 34. Accordingly, the wafer W is placed on the susceptor 30.

In Step S110, the control unit 90 detects the orientation flat Wd of the wafer W using the carrying unit 100 and places the wafer W on the movable portion 32 such that the extending direction of the orientation flat Wd is parallel to the predetermined direction D indicated by the marked portion 36 formed in the susceptor 30. That is, a film forming process of the film formation method according to the first embodiment includes setting the orientation flat Wd to be parallel to the predetermined direction D. Accordingly, the plurality of wafer supports 34 and the wafer W supported by the plurality of wafer supports 34 satisfy the arrangement relationship illustrated in FIGS. 3, 8, and 9. Accordingly, when seen in the vertical direction Z, the direction in which the rotation axis R and each wafer support 34 are connected and the direction in which two arbitrary wafer supports 34 are connected are directions which are different from the cleaving direction of the wafer W, that is, the crystal orientation of the wafer W indicated by <11-20>.

After the wafer W has been placed on the susceptor 30 as illustrated in FIG. 11, the control unit 90 performs the film forming process of forming a film on a surface of the wafer W (Step S120). That is, the film formation method according to the first embodiment includes the film forming process of forming a film on the surface of the wafer W. The film forming process is performed in a state in which the wafer Wis supported by the plurality of wafer supports 34 with the arrangement relationship when the wafer W is placed in Step S110. That is, the film forming process of the film formation method according to the first embodiment includes supporting the wafer W using the plurality of wafer supports 34 such that the direction in which the rotation axis R and each wafer support 34 are connected is a direction which is different from the cleaving direction of the wafer W. The film forming process includes supporting the wafer W using the plurality of wafer supports 34 such that the direction in which two arbitrary wafer supports 34 out of the plurality of wafer supports 34 are connected is a direction which is different from the cleaving direction of the wafer W. The film forming process includes supporting the wafer W using the plurality of wafer supports 34 such that the direction in which the rotation axis R and each wafer support 34 are connected is a direction which is different from the crystal orientation of the wafer W indicated by <11-20>. The film forming process includes supporting the wafer W using the plurality of wafer supports 34 such that the direction in which two arbitrary wafer supports 34 out of the plurality of wafer supports 34 are connected is a direction which is different from the crystal orientation of the wafer W indicated by <11-20>.

In the film forming process, the control unit 90 rotates the wafer W around the rotation axis R (Step S121) and heats the wafer W (Step S122). In the film forming process, the control unit 90 rotates the wafer W around the rotation axis R by rotating the susceptor 30 around the rotation axis R using the drive unit 60. In the film forming process, the control unit 90 heats the wafer W by heating the susceptor 30 using the first heating unit 51 and the second heating unit 52. Rotation of the wafer W and heating of the wafer W are performed until the film forming process ends.

In the film forming process, the control unit 90 controls the temperature of the wafer W (Step S123). In Step S123, the control unit 90 measures the temperature of the wafer W using a temperature sensor which is not illustrated. In Step S123, the control unit 90 controls the first heating unit 51 and the second heating unit 52 on the basis of measurement results from the temperature sensor which is not illustrated. The control unit 90 controls the first heating unit 51 and the second heating unit 52 such that the temperature of the wafer W measured by temperature sensor which is not illustrated is, for example, equal to or higher than 1500° C. and equal to or lower than 1650° C.

In the film forming process, the control unit 90 causes a gas G including a source gas to flow into the chamber 20 via the supply port 21 and supplies the gas G to the wafer W (Step S124). When the top surface Wa of the heated wafer W is supplied with the source gas, an SiC film is formed on the top surface Wa of the wafer W. By continuously supplying the source gas to the wafer W for a predetermined time or more, an SiC film with a desired thickness is formed on the top surface Wa of the wafer W. By supplying the source gas to the top surface Wa of the wafer W while rotating the wafer W around the rotation axis R using the drive unit 60, it is possible to reduce an amount of source gas and unevenness of the source gas in the plane of the top surface Wa of the wafer W. Accordingly, it is possible to enhance uniformity in thickness of the film formed on the wafer W. In the film forming process, the control unit 90 heats the gas G in the supply pipe 24 using the third heating units 53. When the film forming process ends, the control unit 90 stops the drive unit 60 and the heating units and stops supply of the gas G into the chamber 20.

For example, Step S123 of controlling the temperature of the wafer W continues to be normally performed in the film forming process. Step S123 may be performed at intervals of a predetermined time. Step S121 of rotating the wafer W may be started after the wafer W has been heated to a predetermined temperature and before the gas G has been supplied.

After the film forming process ends, the control unit 90 takes out the wafer W from the vapor growth apparatus 10 (Step S130). In Step S130, the control unit 90 moves the movable portion 32 upward using the lifting unit 80 to raise the wafer W. The control unit 90 carries the raised wafer W using the carrying unit 100.

According to the first embodiment, the vapor growth apparatus 10 used for the film formation method includes the susceptor 30 supporting a wafer W. The susceptor 30 includes a plurality of wafer supports 34 supporting the wafer W from below and rotates around the rotation axis R extending in the vertical direction Z. The plurality of wafer supports 34 are arranged at intervals in the circumferential direction around the rotation axis R. In this way, since the plurality of wafer supports 34 are arranged at intervals in the circumferential direction, a part located between neighboring wafer supports 34 at an interval in the circumferential direction in an outer circumferential part of the wafer W does not come into contact with the susceptor 30. Accordingly, in comparison with each wafer support 34 has a ring shape, it is possible to increase the area of the outer circumferential part of the wafer W not in contact with the susceptor 30 and to curb raising of the temperature in that part of the wafer W. As a result, it is possible to prevent a thickness and a carrier concentration of the film formed in the outer circumferential part of the wafer W from being greatly different from the thickness and the carrier concentration of the film formed in the central part of the wafer W and to curb deterioration in a wafer-plane distribution of the film formed on the wafer W in the outer circumferential part of the wafer W. As a result, it is possible to decrease the area of a part which cannot be used as an area in which semiconductor elements are formed on the wafer W on which the film has been formed. Accordingly, it is possible to curb a decrease in yield of semiconductor elements which are manufactured using the wafer W.

According to the first embodiment, the direction in which the rotation axis R and each wafer support 34 are connected when seen in the vertical direction Z is a direction which is different from the cleaving direction of a wafer W. In other words, the film forming process of the film formation method of forming a film on the surface of the wafer W using the vapor growth apparatus 10 includes supporting the wafer W using the plurality of wafer supports 34 such that the direction in which the rotation axis R and each wafer support 34 are connected when seen in the vertical direction Z is a direction which is different from the cleaving direction of the wafer W. Accordingly, it is possible to set a direction in which a heat stress generated in the wafer W due to heat transmitted from the wafer supports 34 acts to be different from the cleaving direction in which the wafer W is likely to crack. As a result, it is possible to curb cracking of the wafer W supported by the plurality of wafer supports 34 or occurrence of a crystal defect, that is, a dislocation, in the wafer W due to a heat stress in the filming forming process. The effect of curbing cracking of the wafer W is preferably obtained when an angle by which the direction in which the rotation axis R and each wafer support 34 are connected when seen in the vertical direction Z is different from the cleaving direction of the wafer W is 5° or more, is more preferably obtained when the angle is 10° or more, and is still more preferably obtained when the angle is 15° or more. The effect of curbing cracking of the wafer W is obtained when the angle by which the direction in which the rotation axis R and each wafer support 34 are connected when seen in the vertical direction Z is different from the cleaving direction of the wafer W is greater than 0°.

According to the first embodiment, the direction in which two arbitrary wafer supports 34 out of the plurality of wafer supports 34 are connected when seen in the vertical direction Z is a direction which is different from the cleaving direction of the wafer W. In other words, the film forming process includes supporting the wafer W using the plurality of wafer supports 34 such that the direction in which two arbitrary wafer supports 34 out of the plurality of wafer supports 34 are connected when seen in the vertical direction Z is a direction which is different from the cleaving direction of the wafer W. Accordingly, even when a heat stress generated in the wafer W due to heat transmitted from the two wafer supports 34 is generated in the direction in which two arbitrary wafer supports 34 out of the plurality of wafer supports 34 are connected, it is possible to set the direction to be different from the cleaving direction in which the wafer W is likely to crack. As a result, it is possible to further curb cracking of the wafer W in the film forming process. The effect of curbing cracking of the wafer W is preferably obtained when an angle by which the direction in which two arbitrary wafer supports 34 are connected when seen in the vertical direction Z is different from the cleaving direction of the wafer Wis 5° or more, is more preferably obtained when the angle is 10° or more, and is still more preferably obtained when the angle is 15° or more. The effect of curbing cracking of the wafer W is obtained when the angle by which the direction in which two arbitrary wafer supports 34 are connected when seen in the vertical direction Z is different from the cleaving direction of the wafer W is greater than 0°.

According to the first embodiment, the wafer W is formed of a single crystal with a crystal structure of a hexagonal crystal system. The direction in which the rotation axis R and each wafer support 34 are connected when seen in the vertical direction Z is a direction which is different from the crystal orientation of the wafer W indicated by <11-20>. In other words, the film forming process includes supporting the wafer W using the plurality of wafer supports 34 such that the direction in which the rotation axis R and each wafer support 34 are connected when seen in the vertical direction Z is a direction which is different from the crystal orientation of the wafer W indicated by <11-20>. Accordingly, it is possible to set a direction in which a heat stress generated in the wafer W due to heat transmitted from the wafer supports 34 acts to be different from the cleaving direction of the wafer W formed of a single crystal with a crystal structure of a hexagonal crystal system. As a result, it is possible to curb cracking of the wafer W formed of a single crystal with a crystal structure of a hexagonal crystal system.

According to the first embodiment, the direction in which two arbitrary wafer supports 34 out of the plurality of wafer supports 34 are connected when seen in the vertical direction Z is a direction which is different from the crystal orientation of the wafer W indicated by <11-20>. In other words, the film forming process includes supporting the wafer W using the plurality of wafer supports 34 such that the direction in which two arbitrary wafer supports 34 out of the plurality of wafer supports 34 are connected when seen in the vertical direction Z is a direction which is different from the crystal orientation of the wafer W indicated by <11-20>. Accordingly, it is possible to curb cracking of the wafer W formed of a single crystal with a crystal structure of a hexagonal crystal system.

According to the first embodiment, the susceptor 30 includes the marked portion 36 indicating the predetermined direction D perpendicular to the vertical direction Z. The direction in which the rotation axis R and each wafer support 34 are connected is a direction which is different from the predetermined direction D and is a direction which is different from a direction oblique by 60° with respect to the predetermined direction D. The wafer W is a SiC substrate. The plate face of the wafer W is a face parallel to the crystal face indicated by (0001). The orientation flat Wd extending in the crystal orientation of the wafer W indicated by <11-20> is provided on the outer edge of the wafer W. The film forming process includes setting the orientation flat Wd to be parallel to the predetermined direction D. Accordingly, as illustrated in FIG. 8, the cleaving direction of the wafer W is an extending direction of the orientation flat Wd and a direction oblique by 60° with respect to the extending direction of orientation flat Wd. As a result, by arranging the wafer supports 34 such that the direction in which the rotation axis R and each wafer support 34 are connected when seen in the vertical direction Z is different from any of the predetermined direction D indicated by the marked portion 36 and the direction oblique by 60° with respect to the predetermined direction D and supporting the wafer W using the plurality of wafer supports 34 such that the orientation flat Wd is parallel to the predetermined direction D, it is possible to set the direction in which the rotation axis R and each wafer support 34 are connected when seen in the vertical direction Z to be different from the cleaving direction of the wafer W with the crystal structure of the hexagonal crystal system. Accordingly, it is possible to curb cracking of the wafer W formed of a single crystal with the crystal structure of the hexagonal crystal system in the film forming process.

For example, when the thickness, the carrier concentration, and the like of a film formed on the surface of the wafer W are measured to ascertain the quality of the wafer W, the thickness, the carrier concentration, and the like of the film are measured at a plurality of positions on a straight line passing through the center Cw of the wafer W with a substantially disc shape and extending in a direction perpendicular to the thickness direction of the wafer W. A direction in which the measurement is performed is determined, for example, on the basis of a direction in which a plurality of semiconductor elements formed on the wafer W are arranged. As indicated by an alternate long and two short dashes line in FIG. 9, on the wafer W provided with the orientation flat Wd, semiconductor elements are formed in a plurality of element formation areas We which are arranged in a matrix shape in the extending direction of the orientation flat Wd and the direction perpendicular to the extending direction of the orientation flat Wd. Accordingly, the measurement of a film is often performed at positions of the wafer W located on measurement lines ML1a and ML1b extending in two directions in which the plurality of element formation areas We are arranged. The measurement line ML1a is a straight line passing through the center Cw of the wafer W and extending in the extending direction of the orientation flat Wd when seen in the thickness direction of the wafer W. The measurement line ML1b is a straight line passing through the center Cw of the wafer W and extending in the direction perpendicular to the extending direction of the orientation flat Wd when seen in the thickness direction of the wafer W. In the film forming process, the temperature in the parts of the wafer W supported by the plurality of wafer supports 34 is likely to become higher than that in the other parts of the wafer W. Accordingly, the thickness and the carrier concentration in the parts of the wafer W supported by the plurality of wafer supports 34 are likely to deviate from average values. As a result, the parts of the wafer W supported by the plurality of wafer supports 34 are not often used to manufacture semiconductor elements. It may not be preferable to perform measurement in a part of the wafer W which is not used to manufacture semiconductor elements.

As described above, according to the first embodiment, the plurality of wafer supports 34 are arranged at positions other than the straight line L1a passing through the rotation axis R and extending in the predetermined direction D when seen in the vertical direction Z and are arranged at positions other than the straight line L1b passing through the rotation axis R and extending in the direction perpendicular to the predetermined direction D. By matching the center Cw of the wafer W with the rotation axis R and disposing the wafer W on the plurality of wafer supports 34 such that the extending direction of the orientation flat Wd matches the predetermined direction D, the straight lines L1a and L1b match the measurement lines ML1a and ML1b used to measure the film on the wafer W when seen in the vertical direction Z. That is, when seen in the vertical direction Z, the straight line L1a matches the measurement line ML1a passing through the center Cw of the wafer W and extending in the extending direction of the orientation flat Wd. When seen in the vertical direction Z, the straight line L1b matches the measurement line ML1b passing through the center Cw of the wafer W and extending in the direction perpendicular to the extending direction of the orientation flat Wd. Since the plurality of wafer supports 34 are arranged at positions other than the straight lines L1a and L1b when seen in the vertical direction Z, the wafer W is supported by the plurality of wafer supports 34 at positions other than the measurement positions on the measurement lines ML1a and ML1b on which measurement is performed after a film has been formed thereon in the film forming process. Accordingly, it is possible to curb measurement of the thickness and the carrier concentration of the parts of the wafer W supported by the plurality of wafer supports 34 in the film forming process.

When the thickness, the carrier concentration, and the like of the film formed on the surface of the wafer W are measured, for example, the measurement of the film formed on the wafer W may be performed in a direction oblique by 45° with respect to two directions in which a plurality of element formation areas We are arranged. In this case, as illustrated in FIG. 9, measurement of the film formed on the wafer W is performed on the measurement lines ML2a and ML2b passing through the center Cw of the wafer W and extending in the direction oblique by 45° with respect to the extending direction of the orientation flat Wd when seen in the thickness direction of the wafer W. The extending direction of the measurement line ML2a and the extending direction of the measurement line ML2b are perpendicular to each other.

On the other hand, according to the first embodiment, the plurality of wafer supports 34 are arranged at positions other than the straight lines L2a and L2b passing through the rotation axis R and extending in the direction oblique by 45° with respect to the predetermined direction D when seen in the vertical direction Z. By matching the center Cw of the wafer W with the rotation axis R and arranging the wafer W on the plurality of wafer supports 34 such that the extending direction of the orientation flat Wd matches the predetermined direction D, the straight lines L2a and L2b match the measurement lines ML2a and ML2b used to measure the film of the wafer W when seen in the vertical direction Z. Accordingly, even when measurement of the film on the wafer W is performed along the measurement lines ML2a and ML2b, it is possible to curb measurement of the thickness and the carrier concentration of the parts of the wafer W supported by the plurality of wafer supports 34 in the film forming process.

The effect of curbing measurement of the thickness and the carrier concentration of the parts of the wafer W supported by the plurality of wafer supports 34 in the film forming process is preferable obtained when the plurality of wafer supports 34 are separated by 5 mm or more from the straight lines L1a, L1b, L2a, and L2b when seen in the vertical direction Z and is more preferable obtained when the plurality of wafer supports 34 are separated by 10 mm or more from the straight lines L1a, L1b, L2a, and L2b.

According to the first embodiment, the plurality of wafer supports 34 include a pair of wafer supports 34 with the rotation axis R interposed therebetween when seen in the vertical direction Z. Accordingly, it is possible to easily stably support the wafer W using the plurality of wafer supports 34.

According to the first embodiment, the number of wafer supports 34 is equal to or greater than four. Accordingly, in comparison with a case in which the number of wafer supports 34 is equal to or less than three, it is possible to stably support the wafer W using the plurality of wafer supports 34. Since the number of wafer supports 34 is equal to or greater than four, a force applied from the wafer W to each wafer support 34 can be decreased in comparison with a case in which the number of wafer supports 34 is equal to or less than three. As a result, it is possible to curb abrasion of the plurality of wafer supports 34 due to contact with the wafer W.

According to the first embodiment, the susceptor 30 includes the base 31 which is separate from the plurality of wafer supports 34. The base 31 includes a plurality of fixing holes 35a which are open upward and arranged at intervals in the circumferential direction. The plurality of wafer supports 34 are fixed into the plurality of fixing holes 35a and protrude upward from the plurality of fixing holes 35a. Accordingly, in comparison with a case in which the base 31 and the plurality of wafer supports 34 are formed as a unified body, it is possible to make it difficult to transmit heat from the base 31 to the wafer supports 34. As a result, it is possible to curb raising of the temperature of a part in contact with each wafer support 34 in the outer circumferential part of the wafer W. Accordingly, it is possible to curb the temperature of the outer circumferential part of the wafer W becoming higher than that of the central part of the wafer W in the film forming process. As a result, it is possible to prevent the thickness and the carrier concentration of the film formed in the outer circumferential part of the wafer W from becoming greatly different from the thickness and the carrier concentration of the film formed in the central part of the wafer W. Accordingly, it is possible to further curb deterioration of the wafer-plane distribution of the film formed on the wafer W in the outer circumferential part of the wafer W. As a result, it is possible to further reduce a part which cannot be used as an area in which semiconductor elements are formed on the wafer W on which the film has been formed. Accordingly, it is possible to further curb a decrease in yield of semiconductor elements which are manufactured using the wafer W.

According to the first embodiment, in each of the plurality of wafer supports 34, at least a part of the outer circumferential surface of a part of the wafer support 34 located in the fixing hole 35a is separated from the inner surface of the fixing hole 35a. Accordingly, in comparison with a case in which the outer circumferential surface of each wafer support 34 is in contact with the inner surface of the corresponding fixing hole 35a as a whole, it is possible to make it difficult to transmit heat from the base 31 to each wafer support 34. As a result, it is possible to further curb raising of the temperature in the parts of the wafer W in contact with the plurality of wafer supports 34.

According to the first embodiment, each of the plurality of wafer supports 34 includes the body portion 34a extending in the vertical direction Z and the protruding portion 34b provided on the outer circumferential surface of the body portion 34a. The protruding portion 34b comes into contact with the inner surface of the fixing hole 35a. Accordingly, it is possible to separate a part of the outer circumferential surface of each wafer support 34 from the inner surface of the corresponding fixing hole 35a while fixing the wafer support 34 into the fixing hole 35a via the protruding portion 34b.

On the bottom surface Wb of the wafer W, a scar is left at the positions having come into contact with the plurality of wafer supports 34. Accordingly, by checking the scar on the bottom surface Wb of the wafer W on which a film has been formed, it is possible to ascertain a relationship between the positions at which the wafer W is supported in the film forming process and the cleaving direction of the wafer W and a relationship between the positions at which the wafer W is supported in the film forming process and the positions at which a film on the wafer W is measured.

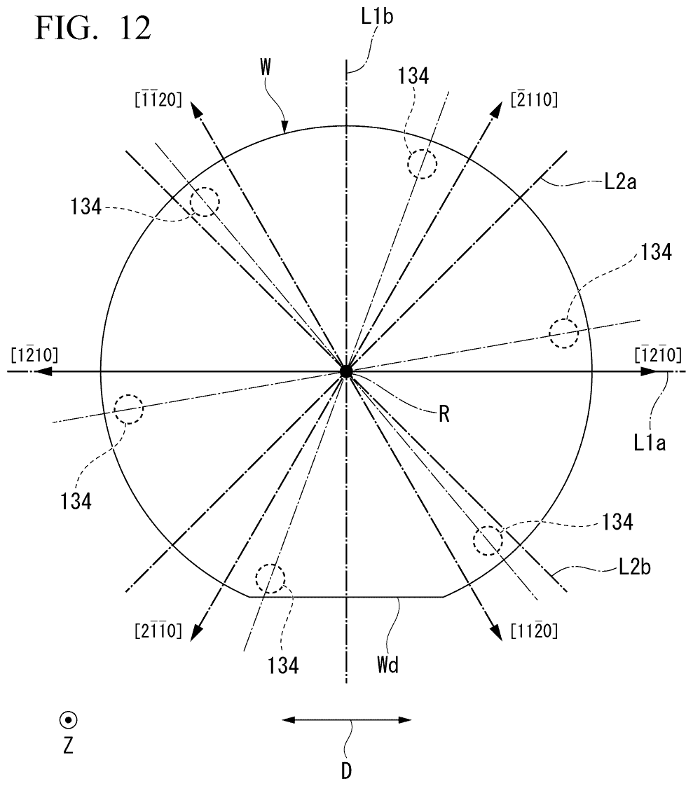

The number of wafer supports 34 is not limited to four as long as it is equal to or greater than two. The number of wafer supports 34 may be six as wafer supports 134 illustrated in FIG. 12. FIG. 12 is a diagram illustrating a plurality of wafer supports 134 according to a modified example of the first embodiment. Regarding six wafer supports 134 illustrated in FIG. 12, the arrangement relationship between the cleaving direction of the wafer W and the predetermined direction D is the same as in the aforementioned wafer supports 34.

Embodiments other than the aforementioned embodiment will be described below. In the following description of the embodiments, by appropriately adding the same reference signs to the same configuration as the configuration described prior to description of each embodiment, description thereof may be omitted. Elements corresponding to the constituents of the configuration described prior to description of each embodiment may be labeled by the same names and referred to by different reference signs, differences from the previously described configuration may be described, and description of the same configuration as described prior may be omitted. As a configuration of which description is omitted in the following embodiments, the same configuration as the configuration described prior to each embodiment can be employed unless confliction arises.

### Second Embodiment

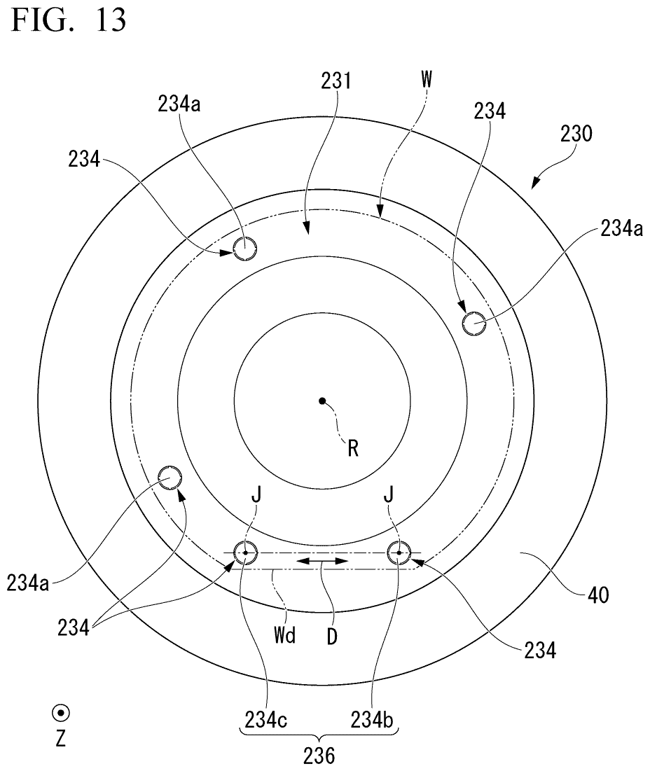

FIG. 13 is a top view of a susceptor 230 according to a second embodiment. In FIG. 13, an outline of a wafer W is indicated by an alternate long and two short dashes line. As illustrated in FIG. 13, the susceptor 230 includes five wafer supports 234. The five wafer supports 234 include three wafer supports 234a, one wafer support 234b, and one wafer support 234c. Four wafer supports 234 including the three wafer supports 234a and the one wafer support 234b are arranged in the same way as four wafer supports 34 in the first embodiment.

The wafer support 234b is disposed at the same position as the wafer support 34 supporting a part of the outer edge in the radial direction of the wafer W located inside of the orientation flat Wd in the radial direction out of the four wafer supports 34 in the first embodiment. The wafer support 234c is disposed at a position neighboring the wafer support 234b in the circumferential direction. The wafer support 234c supports a part of the outer edge in the radial direction of the wafer W located inside of the orientation flat Wd in the radial direction.

In the second embodiment, the wafer support 234b and the wafer support 234c form a marked portion 236. A direction in which the wafer support 234b and the wafer support 234c are connected when seen in the vertical direction Z is the predetermined direction D. That is, in the second embodiment, the marked portion 236 indicates the predetermined direction D which the orientation flat Wd provided on the outer edge of the wafer W is set to be parallel to when the wafer W is supported by the plurality of wafer supports 234 using the direction in which the two wafer supports 234b and 234c are arranged. In FIG. 13, an extending direction of a straight line connecting the center axis J of the wafer support 234b and the center axis J of the wafer support 234c when seen in the vertical direction Z is the predetermined direction D.

A base 231 is the same as the base 31 in the first embodiment except that the fixing hole into which the wafer support 234c is fixed is provided. The other configuration of the susceptor 230 is the same as the other configuration of the susceptor 30 in the first embodiment.

### Third Embodiment

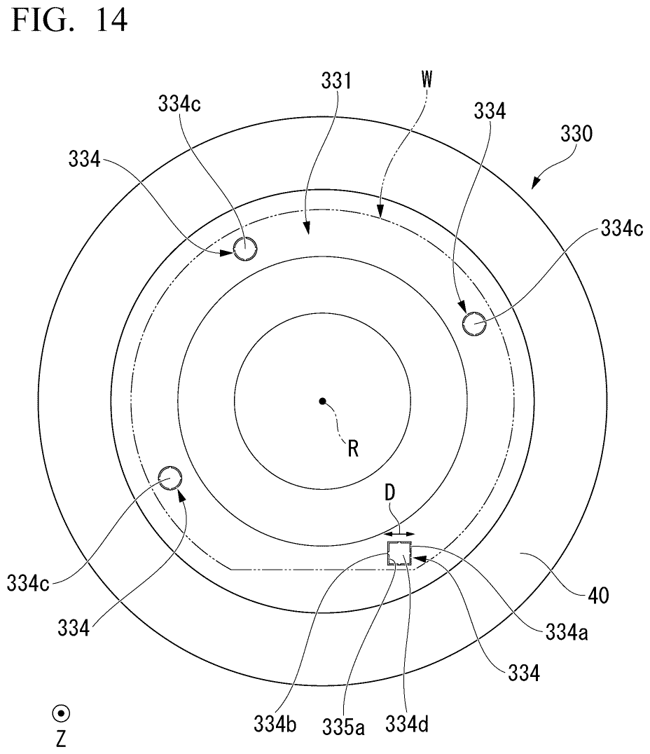

FIG. 14 is a top view of a susceptor 330 according to a third embodiment. In FIG. 14, an outline of a wafer W is indicated by an alternate long and two short dashes line. As illustrated in FIG. 14, the susceptor 330 includes four wafer supports 334. The four wafer supports 334 are arranged in the same way as in the four wafer supports 34 of the first embodiment. The four wafer supports 334 include three wafer supports 334c and one wafer support 334d. The shape of the three wafer supports 334c is the same as the shape of the wafer supports 34 in the first embodiment.

When seen in the vertical direction Z, a shape of the one wafer support 334d is different from the shape of the three wafer supports 334c. The wafer support 334d includes a body portion 334a and a plurality of protruding portions 334b. The body portion 334a of the wafer support 334d has a rectangular shape when seen in the vertical direction Z. In the third embodiment, the wafer support 334d is a marked portion indicating the predetermined direction D. In FIG. 14, a side extending in a lateral direction out of sides of the body portion 334a in the wafer support 334d which is rectangular when seen in the vertical direction Z indicates the predetermined direction D. For example, the control unit 90 can dispose the orientation flat Wd in the predetermined direction D by disposing the wafer W such that the orientation flat Wd is closest to the wafer support 334d which is the marked portion out of four wafer supports 334 and the orientation flat Wd is parallel to one side of the wafer support 334d. The plurality of protruding portions 334b are the same as the plurality of protruding portions 34b in the first embodiment except that they are provided on the sides of the body portion 334a which is rectangular when seen in the vertical direction Z.

A base 331 is the same as the base 31 in the first embodiment except that the shape of a fixing hole 335a into which the wafer support 334d is fixed is rectangular when seen in the vertical direction Z. The other configuration of the susceptor 330 is the same as the other configuration of the susceptor 30 in the first embodiment. In the third embodiment, the fixing hole 335a into which the wafer support 334d is fixed may be a marked portion. In this case, the predetermined direction D is indicated by a side of the fixing hole 335a which is rectangular when seen in the vertical direction Z.

The film formation method according to at least one of the aforementioned embodiments is a film formation method of forming a film on a surface of a wafer using a vapor growth apparatus. The film formation method according to the embodiments includes a film forming process of forming a film on the surface of the wafer. The vapor growth apparatus includes a susceptor that supports the wafer. The susceptor includes a plurality of wafer supports that support the wafer from below and rotates around a rotation axis extending in a vertical direction. The plurality of wafer supports are arranged at intervals in a circumferential direction around the rotation axis. The film forming process includes supporting the wafer using the plurality of wafer supports such that a direction in which the rotation axis and each wafer support are connected when seen in the vertical direction is a direction which is different from a cleaving direction of the wafer. Accordingly, as described above, it is possible to curb a decrease in yield of semiconductor elements which are manufactured by the wafer. It is possible to curb cracking of the wafer in the film forming process.

When at least a part of the outer circumferential surface of a part of each wafer support located in the corresponding fixing hole is separated from the inner surface of the fixing hole, the plurality of wafer supports may be fixed into the plurality of fixing holes in any way.

The whole outer circumferential surface of a part of each wafer support located in the corresponding fixing hole may be in contact with the inner surface of the fixing hole. The wafer supports may not be separated from the base, but may be formed as a unified body with the base. In this case, since the plurality of wafer supports are arranged at intervals in the circumferential direction, it is possible to curb a decrease in yield of semiconductor elements which are manufactured using the wafer as described above. Since the direction in which the rotation axis and each wafer support are connected when seen in the vertical direction is a direction which is different from the cleaving direction of the wafer, it is possible to curb cracking of the wafer in the film forming process and thus to further curb a decrease in yield of semiconductor elements which are manufactured using the wafer.

The material of the plurality of wafer supports may be different from the material of the base of the susceptor. In this case, a thermal conductivity of the plurality of wafer supports may be lower than the thermal conductivity of the base of the susceptor. In this case, it is possible to further curb transmission of heat from the base of the susceptor to the plurality of wafer supports. Accordingly, it is possible to further curb raising of the temperature of the parts of the wafer in contact with the plurality of wafer supports. When the thermal conductivity of the plurality of wafer supports is lower than the thermal conductivity of the base of the susceptor, for example, graphite, SiC, or SiN, or the like can be employed as the material of the plurality of wafer supports.

The direction in which the rotation axis and each wafer support are connected when seen in the vertical direction may be an extending direction of a straight line passing through the rotation axis and each wafer support when seen in the vertical direction. The direction in which two wafer supports are connected when seen in the vertical direction may be an extending direction of a straight line passing through the two wafer supports when seen in the vertical direction. The marked portion may have any shape as long as it can indicate a predetermined direction which the orientation flat is set to be parallel to, and may be formed at any position of the susceptor. The marked portion may not be formed in the susceptor.

While certain embodiments have been described, these embodiments have been presented only as exemplary examples, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A film formation method of forming a film on a surface of a wafer using a vapor growth apparatus, the film formation method comprising a film forming process of forming a film on the surface of the wafer,
wherein the vapor growth apparatus includes a susceptor that supports the wafer,
wherein the susceptor includes a plurality of wafer supports that support the wafer from below and rotates around a rotation axis extending in a vertical direction,
wherein the plurality of wafer supports are arranged at intervals in a circumferential direction around the rotation axis, and
wherein the film forming process includes supporting the wafer using the plurality of wafer supports such that a direction in which the rotation axis and each wafer support are connected when seen in the vertical direction is a direction which is different from a cleaving direction of the wafer.

2. The film formation method according to claim 1, wherein the film forming process includes supporting the wafer using the plurality of wafer supports such that a direction in which two arbitrary wafer supports out of the plurality of wafer supports are connected when seen in the vertical direction is a direction which is different from the cleaving direction of the wafer.

3. The film formation method according to claim 1, wherein the wafer is formed of single crystals with a crystal structure of a hexagonal crystal system, and
wherein the film forming process includes supporting the wafer using the plurality of wafer supports such that a direction in which the rotation axis and each wafer support are connected when seen in the vertical direction is a direction which is different from a crystal orientation of the wafer indicated by <11-20>.

4. The film formation method according to claim 3, wherein the film forming process includes supporting the wafer using the plurality of wafer supports such that a direction in which two arbitrary wafer supports out of the plurality of wafer supports are connected when seen in the vertical direction is a direction which is different from the crystal orientation of the wafer indicated by <11-20>.

5. The film formation method according to claim 3, wherein the susceptor includes a marked portion indicating a predetermined direction perpendicular to the vertical direction,
wherein the direction in which the rotation axis and each wafer support are connected when seen in the vertical direction is a direction which is different from the predetermined direction and is a direction which is different from a direction oblique by 60° with respect to the predetermined direction,
wherein the wafer is a SiC substrate,
wherein a plate face of the wafer is a plane parallel to a crystal face indicated by (0001),
wherein an orientation flat extending in the crystal orientation of the wafer indicated by <11-20> is provided on an outer edge of the wafer, and
wherein the film forming process includes setting the orientation flat to be parallel to the predetermined direction.

6. The film formation method according to claim 5, wherein the plurality of wafer supports are arranged at positions other than a straight line passing through the rotation axis and extending in the predetermined direction when seen in the vertical direction and are arranged at positions other than a straight line passing through the rotation axis and extending in a direction perpendicular to the predetermined direction.

7. The film formation method according to claim 5, wherein the plurality of wafer supports are arranged at positions other than a straight line passing through the rotation axis and extending in a direction oblique by 45° with respect to the predetermined direction when seen in the vertical direction.

8. The film formation method according to claim 1, wherein the plurality of wafer supports include a pair of wafer supports with the rotation axis interposed therebetween when seen in the vertical direction.

9. The film formation method according to claim 1, wherein the number of wafer supports is equal to or greater than four.

10. A susceptor that is provided in a vapor growth apparatus, supports a wafer, and rotates around a rotation axis extending in a vertical direction, the susceptor comprising:
a plurality of wafer supports that support the wafer from below; and
a marked portion that indicates a predetermined direction perpendicular to the vertical direction,
wherein the plurality of wafer supports are arranged at intervals in a circumferential direction around the center axis, and
wherein a direction in which the rotation axis and each wafer support are connected when seen in the vertical direction is a direction which is different from the predetermined direction and which is different from a direction oblique by 60° with respect to the predetermined direction.

11. The susceptor according to claim 10, wherein the plurality of wafer supports are arranged at positions other than a straight line passing through the rotation axis and extending in the predetermined direction when seen in the vertical direction and are arranged at positions other than a straight line passing through the rotation axis and extending in a direction perpendicular to the predetermined direction.

12. The susceptor according to claim 10, wherein the plurality of wafer supports are arranged at positions other than a straight line passing through the rotation axis and extending in a direction oblique by 45° with respect to the predetermined direction when seen in the vertical direction.

13. The susceptor according to claim 10, wherein the plurality of wafer supports include a pair of wafer supports with the rotation axis interposed therebetween when seen in the vertical direction.

14. The susceptor according to claim 10, wherein the number of wafer supports is equal to or greater than four.

15. The susceptor according to claim 10, further comprising a base which is separable from the plurality of wafer supports,
wherein the base includes a plurality of fixing holes which are open upward and arranged at intervals in the circumferential direction, and
wherein the plurality of wafer supports are fixed into the plurality of fixing holes and protrude upward from the plurality of fixing holes.

16. The susceptor according to claim 15, wherein at least a part of an outer circumferential surface of a part of a wafer support located in the fixing hole in each of the plurality of wafer supports is separated from an inner surface of the fixing hole.

17. The susceptor according to claim 16, wherein each of the plurality of wafer supports includes:
a body portion extending in the vertical direction; and
a protruding portion provided on an outer circumferential surface of the body portion, and
wherein the protruding portion comes into contact with the inner surface of the fixing hole.

18. The susceptor according to claim 15, wherein a thermal conductivity of the plurality of wafer supports is lower than a thermal conductivity of the base.

19. A vapor growth apparatus comprising:
a susceptor that is provided in the vapor growth apparatus, supports a wafer, and rotates around a rotation axis extending in a vertical direction;
a drive unit configured to rotate the susceptor around the rotation axis; and
a heating unit configured to heat the susceptor,
wherein the susceptor includes
a plurality of wafer supports that support the wafer from below, and
a marked portion that indicates a predetermined direction perpendicular to the vertical direction,
wherein the plurality of wafer supports are arranged at intervals in a circumferential direction around the center axis, and
wherein a direction in which the rotation axis and each wafer support are connected when seen in the vertical direction is a direction which is different from the predetermined direction and which is different from a direction oblique by 60° with respect to the predetermined direction.
